(19) United States
(12) Patent Application Publication
(10) Pub. No.: US 2012/0097106 A1
(43) Pub. Date: Apr. 26, 2012

(54) PHYSICAL VAPOR DEPOSITION DEVICE FOR COATING WORKPIECE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 13/037,126

(22) Filed: Feb. 28, 2011

(30) Foreign Application Priority Data
Oct. 26, 2010 (TW) 99136432

(51) Int. Cl. C23C 16/458

(52) U.S. Cl. 118/730

(57) ABSTRACT

A physical vapor deposition device includes a deposition chamber, a workpiece carrier received in the deposition chamber, at least one cylindrical inner target, and a plurality of cylindrical outer targets. The workpiece carrier is rotatable about a rotation axis thereof. The workpiece carrier includes an inner carrier, and an outer carrier surrounding and being fixed relative to the inner carrier. The inner target is located at a central area of the inner carrier. The outer targets surround the outer carrier.

### BACKGROUND

1. Technical Field

The present disclosure relates to a physical vapor deposition device for coating workpiece.

2. Description of Related Art

Physical vapor deposition (PVD) devices are widely used to form functional or decorative metallic films on workpieces. A typical PVD device usually includes a deposition chamber, a deposition carrier and a number of targets positioned in the deposition chamber. The deposition carrier is a single assembly with a number of posts for supporting a number of workpieces. The targets are positioned on opposite sides of the deposition carrier, and each of the targets is planar.

However, because of the small distance between the two opposite targets and the opposite surfaces of the planar targets, the two opposite targets will easily influence each other. Thus, the deposition quality of the workpieces will be influenced.

Therefore, a physical vapor deposition device which can overcome the above-mentioned problems is desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an isometric view of a physical vapor deposition device including a workpiece carrier according to an exemplary embodiment.

FIG. 2 is a top planer view of the physical vapor deposition device of FIG. 1.

FIG. 3 is a cutaway view of the workpiece carrier of FIG. 1.

FIG. 4 is a cross-section of the workpiece carrier of FIG. 3.

### DETAILED DESCRIPTION

Embodiments will now be described in detail below with reference to the drawings.

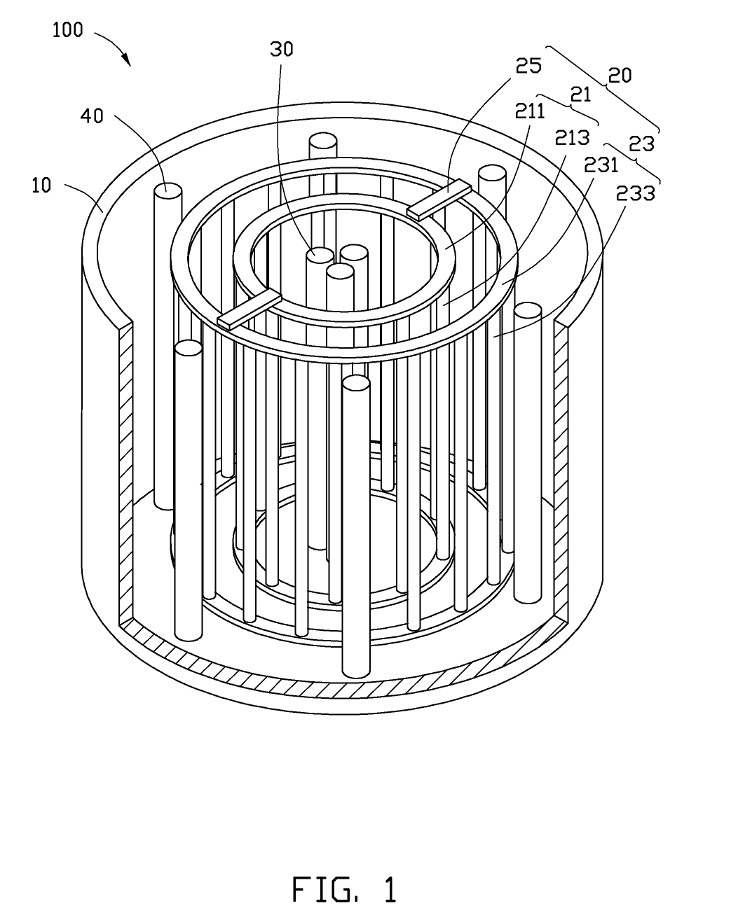

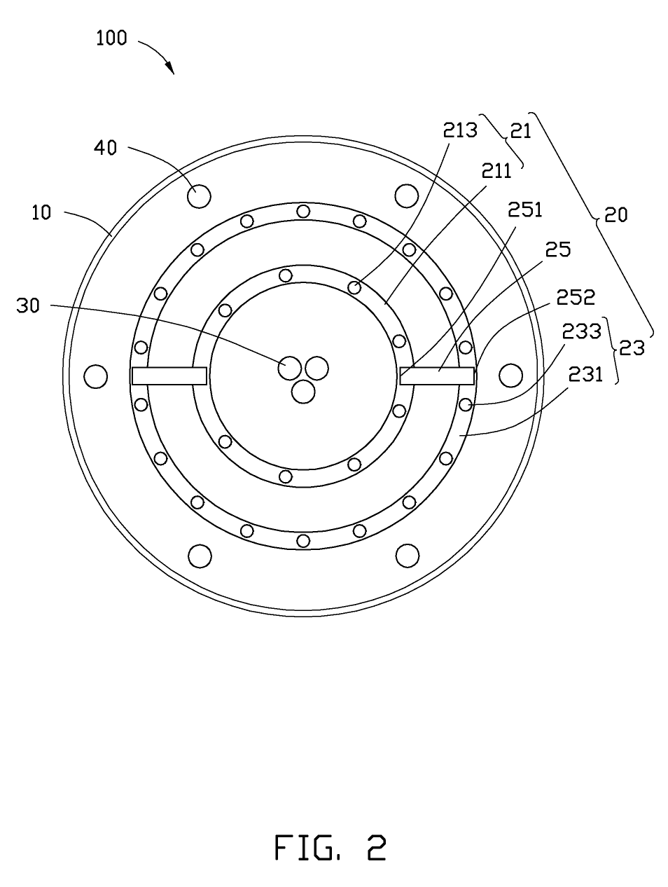

Referring to FIGS. 1-2, a physical vapor deposition device 100 for coating workpieces in accordance with an exemplary embodiment is provided. The physical vapor deposition device 100 includes a deposition chamber 10, a workpiece carrier 20, three inner targets 30, and six outer targets 40.

The deposition chamber 10 is a vacuum chamber. All of the following, the workpiece carrier 20, the three inner targets 30, and the six outer targets 40 are in the deposition chamber 10.

The workpiece carrier 20 is received in the deposition chamber 10, and able to rotate around a rotation axis. The workpiece carrier 20 includes an inner carrier 21, an outer carrier 23, and two connecting arms 25. In this embodiment, the workpiece carrier 20 is located at the central area of the deposition chamber 10. The rotation axis of the workpiece carrier 20 and the central axis of the deposition chamber 10 are coaxial to each other. The inner carrier 21 and the outer carrier 23 are used for supporting workpieces. The connecting arms 25 are used to fixedly fasten the inner carrier 21 and the outer carrier 23.

The inner carrier 21 has an inner annular frame 211, and a number of inner posts 213. The inner posts 213 extend from the inner annular frame 211, and are substantially parallel to each other. In this embodiment, the inner posts 213 are arranged on the inner annular frame 211 with uniform intervals. Each of the inner posts 213 is able to rotate around its central axis.

The outer carrier 23 has an outer annular frame 231, and a number of outer posts 233. The outer posts 233 extend from the outer annular frame 231, and are substantially parallel to each other. In this embodiment, the outer posts 233 are arranged on the outer annular frame 231 with uniform intervals. Each of the outer posts 233 is able to rotate around its central axis.

The inner carrier 21 and the outer carrier 23 are concentric with the rotation axis. The inner carrier 21 is inside the outer carrier 23. The outer posts 233 of the outer carrier 23 are surrounding the inner carrier 21. Each of the outer posts 233 and the inner posts 213 are substantially parallel to each other, and are substantially parallel to the rotation axis of the workpiece carrier 20.

The connecting arms 25 are used to fixedly fasten the inner carrier 21 and the outer carrier 23. Therefore, the inner carrier 21 and the outer carrier 23 can simultaneously rotate around the rotation axis. In this embodiment, the connecting arms 25 are located on the top of the inner carrier 21 and the outer carrier 23, and opposite to each other. The connecting arms 25 are between the inner carrier 21 and the outer carrier 23, and fasten the inner carrier 21 and the outer carrier 23. Each of the connecting arms 25 has a first end 251, and a second end 252 opposite to the first end 251. The first end 251 is fastened to the inner annular frame 211 of the inner carrier 21. The second end 252 is fastened to the outer annular frame 231 of the outer carrier 23. Therefore, the inner carrier 21 and the outer carrier 23 cooperatively form the workpiece carrier 20.

The connecting arms 25 can fasten the inner carrier 21 and the outer carrier 23 with bolts and nuts, or cotter pins and holes, or other mechanisms.

Each of the inner targets 30 and the outer targets 40 is cylindrical, and used for supporting a deposition source. In this embodiment, each central axis of the inner targets 30 and the outer targets 40 is substantially parallel to the rotation axis of the workpiece carrier 20. Each of the inner targets 30 and the outer targets 40 is able to rotate around its own central axis.

The three inner targets 30 are located at the central area of the inner carrier 21, and surround the rotation axis of the workpiece carrier 20 with uniform intervals. The central angle between every two inner targets 30 is 120 degrees. The six outer targets 40 are located outside the outer carrier 23, and surround the outer carrier 23 with uniform intervals. The central angle between every two adjacent outer targets 40 is 60 degrees.

In an alternative embodiment, the physical vapor deposition device 100 can include only one inner target 30 at the central area of the inner carrier, and four or eight or more outer targets 40 outside the outer carrier 23.

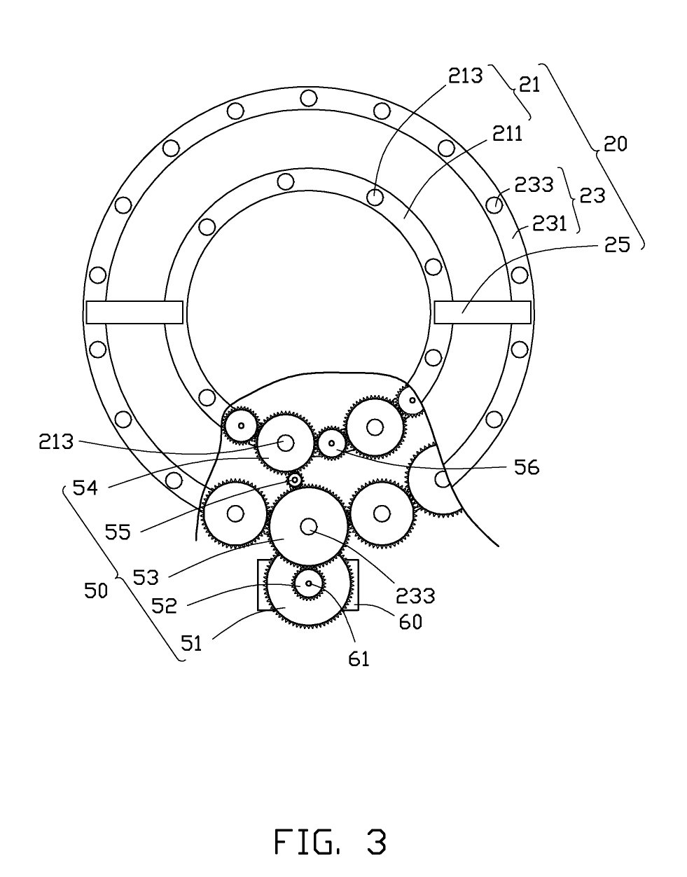

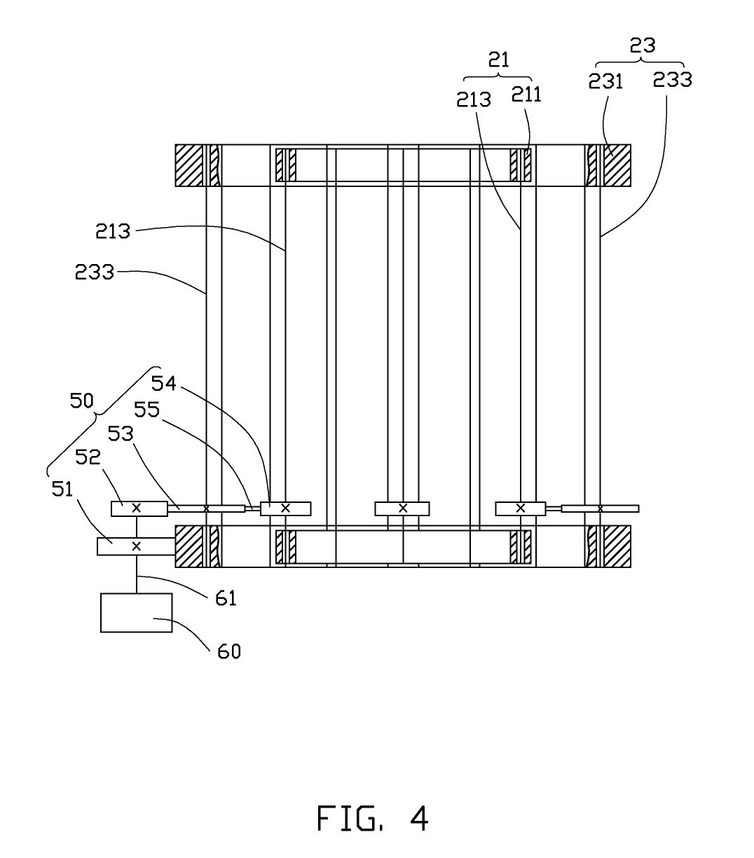

Referring to FIGS. 3-4, the physical vapor deposition device 100 further includes a gear transmission mechanism 50, and a drive member 60. The gear transmission mechanism 50 engages with the inner carrier 21 and the outer carrier 23, and is driven by the drive member 60. Therefore, the workpiece carrier 20 can be driven to rotate around the rotation axis and each of the inner posts 213 and the outer posts 233 simultaneously can be driven to rotate around its own axis.

In this embodiment, the gear transmission mechanism 50 is equipped to the workpiece carrier 20, and located in the bottom of the workpiece carrier 20. The gear transmission 50 includes a first drive gear 51, a second drive gear 52, a plurality of first slave gears 53 and second slave gears 54, a first idler gear 55, and a plurality of second idler gears 56. The drive member 60 includes a motor (not shown) having a drive shaft 61. The first drive gear 51 and the second drive gear 52 are fixedly coupled to the drive shaft 61. The first slave gears 53 are fixedly coupled to the respective outer posts 233. The second slave gears 54 are fixedly coupled to the respective inner posts 213. The first drive gear 51 engages with the teeth (see FIG. 4) formed on circumferential periphery of the outer annular frame 231 of the outer carrier 23. The second drive gear 52 engages with a first slave gear 53 coupled to one of the outer posts 233. The first slave gear 53 engages with the second slave gear 54 with the first idler gear 55. Every two adjacent first slave gears 53 directly engage with each other. Every two adjacent second slave gears 54 engage with one of the second idler gears 56. The gear ratio between the first drive gear 51 and the outer carrier 23 is different from the gear ratio between the second drive gear 52 and the first slave gear 53. Therefore, the drive member 60 can effectively drive the inner carrier 21 and the outer carrier 23 to simultaneously rotate around the rotation axis, and each of the inner posts 213 and outer posts 233 to rotate around its own axis.

It is to be understood that in an alternative embodiment, a belt transmission mechanism or a chain transmission mechanism can be equipped to the workpiece carrier 20.

In operation, the drive member 60 drives the workpiece carrier 20 rotate around the rotation axis, and each of the inner posts 213 and outer posts 233 rotates around its own central axis. Therefore, the workpieces supported on the inner posts 213 and the outer posts 233 can face the deposition sources on the inner targets 30 and the outer targets 40 in different directions. Accordingly, the deposition angel of the workpieces can be adjusted. Finally, the resultant material from the deposition source is deposited onto the workpieces from different direction.

It is to be understood that each of the inner targets 30 and the outer targets 40 can be driven to rotate around its own axis.

Due to the cylindrical inner targets 30 arranged in the central area of the inner carrier 21, and the cylindrical outer targets 40 arranged outside the outer carrier 23, the opposite surfaces between different targets can be greatly reduced. Therefore, the physical vapor deposition device 100 can greatly reduce the possibility of influence between different targets. Besides, as a result of the inner carrier 21 and the outer carrier 23 being concentric to each other, the physical vapor deposition device 100 can have more posts arranged for supporting more workpieces. Therefore, the yield of the deposited workpieces can be substantially increased. Additionally, each of the inner targets 30 and the outer targets 40 can rotate around its own axis. Therefore, it can greatly increase the utilization of the deposition sources supported on the inner targets 30 and the outer targets 40.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A physical vapor deposition device, comprising:
a deposition chamber; and
a workpiece carrier received in the deposition chamber, the workpiece carrier being rotatable about a rotation axis thereof the workpiece carrier comprising an inner carrier, and an outer carrier surrounding the inner carrier, the outer carrier being fixed relative to the inner carrier;
at least one cylindrical inner target located at a central area of the inner carrier, and
a plurality of cylindrical outer targets surrounding the outer carrier.

2. The physical vapor deposition device of claim 1, wherein each of the inner target and the outer targets is rotatable about a central axis thereof.

3. The physical vapor deposition device of claim 1, wherein the at least one cylindrical inner target comprises three inner targets, the three inner targets are located at the central area of the inner carrier, and surround the rotation axis of the workpiece carrier.

4. The physical vapor deposition device of claim 1, wherein the outer targets comprise six outer targets, the six outer targets are located outside the outer carrier, and surround the rotation axis of the workpiece carrier.

5. The physical vapor deposition device of claim 1, wherein the workpiece carrier further comprises two connecting arms, the two connecting arms are located on opposite sides of the inner carrier.

6. The physical vapor deposition device of claim 5, wherein the inner carrier is fixed relative to the outer carrier by means of the connecting arms.

7. The physical vapor deposition device of claim 1, wherein each of the inner carrier and the outer carrier includes a plurality of posts substantially parallel to each other, each of the posts is parallel to the rotation axis of the workpiece carrier, and rotatable about a central axis thereof.

8. The physical vapor deposition device of claim 7, further comprising a transmission mechanism, wherein the transmission mechanism engages with the inner carrier and the outer carrier.

9. The physical vapor deposition device of claim 8, wherein the transmission mechanism includes a first drive gear, a second drive gear, a plurality of first slave gears fixedly coupled to the respective posts arranged on the outer carrier, a plurality of second slave gears fixedly coupled to the respective posts arranged on the inner carrier, and at least one idler gear meshed with one of the first slave gears and one of the second slave gears.

10. The physical vapor deposition device of claim 9, further comprising a drive member for driving the gear transmission mechanism.

11. The physical vapor deposition device of claim 10, wherein the drive member includes a motor having a drive shaft, the first and second drive gears are fixedly coupled to the drive shaft, the first drive gear engages with the outer carrier, the second drive gear engages with one of the first slave gears.

12. The physical vapor deposition device of claim 11, wherein each of the inner and outer targets is parallel with the rotation axis of the workpiece carrier.

13. A physical vapor deposition device comprising:
a deposition chamber;
a workpiece carrier received in the deposition chamber, the workpiece carrier being rotatable about a rotation axis thereof; the workpiece carrier comprising:
an inner carrier having a inner annular frame, and a plurality of inner posts extending from the inner frame, the inner carrier including a plurality of teeth formed on the circumferential periphery of the inner frame;
an outer carrier surrounding the inner carrier, the outer carrier having an outer annular frame, and a plurality of outer posts extending from the outer frame;
a connecting member fixedly interconnected between the inner and outer frame;
a drive assembly comprising:
a plurality of first slave gears fixedly coupled to the respective outer posts, each two adjacent first slave gears meshed with each other;
a plurality of second slave gears fixedly coupled to the respective inner posts;
a first idler gear meshed with one of the first slave gears and one of the second slave gears;
a plurality of second idler gears each meshed with and between each two adjacent second slave gears;
a motor having a drive shaft;
a first drive gear meshed with the teeth of the first carrier; and
a second drive gear meshed with one of the first slave gears, the first and second drive gears fixedly coupled to the drive shaft;
at least one cylindrical inner target located at a central area of the inner carrier; and
a plurality of cylindrical outer targets surrounding the outer carrier.

14. The physical vapor deposition device of claim 13, wherein the connecting member comprises two connecting arms, the two connecting arms are located on opposite sides of the inner carrier.

15. The physical vapor deposition device of claim 14, wherein the inner carrier is fixed relative to the outer carrier by means of the connecting arms.

16. The physical vapor deposition device of claim 13, wherein each of the inner target and the outer targets is rotatable about a central axis thereof.

17. The physical vapor deposition device of claim 13, wherein the at least one cylindrical inner target comprises three inner targets, the three inner targets are located at the central area of the inner carrier, and surround a rotation central axis of the workpiece carrier.

18. The physical vapor deposition device of claim 13, wherein the outer targets comprise six outer targets, the six outer targets are located outside the outer carrier, and surround the rotation axis of the workpiece carrier.

19. The physical vapor deposition device of claim 13, wherein each of the inner and outer targets is parallel with the rotation axis of the workpiece carrier.
